(19) United States
(12) Patent Application Publication
(10) Pub. No.: US 2006/0202749 A1
(43) Pub. Date: Sep. 14, 2006

(54) MPAS

(76) Inventor: Willie Jerry Skipper, Decatur, GA (US)

Correspondence Address: Willie J. Skipper, 3599 Warbler Drive, Decatur, GA, 30034, US

(21) Appl. No.: 11/371,378

(22) Filed: Mar. 7, 2006

Related U.S. Application Data
(60) Provisional application No. 60/659,108, filed on Mar. 8, 2005.

(51) Int. Cl. H03F 3/04; H01S 1/00

(52) U.S. Cl. 330/5

(57) ABSTRACT

The MPAS (Mini Musical Amplification System), is state of the art technology from two major companies. Roland Corporation and Apple/McIntosh Corporation integrated into my new invention called the MPAS. The unit can be interfaced with computers I order to download musical files, thereby giving the artist complete control and freedom of the musical library. The MPAS is a combo machine that accompanies the artist vocals and instrument: The MPAS is able to playback selected tracks with an array of different effects. The invention specs contain no new matter and are a continuation of a previous provisional application (The reference No. 60/659,108 was filed Mar. 8, 2005. Confirmation No: 8112).

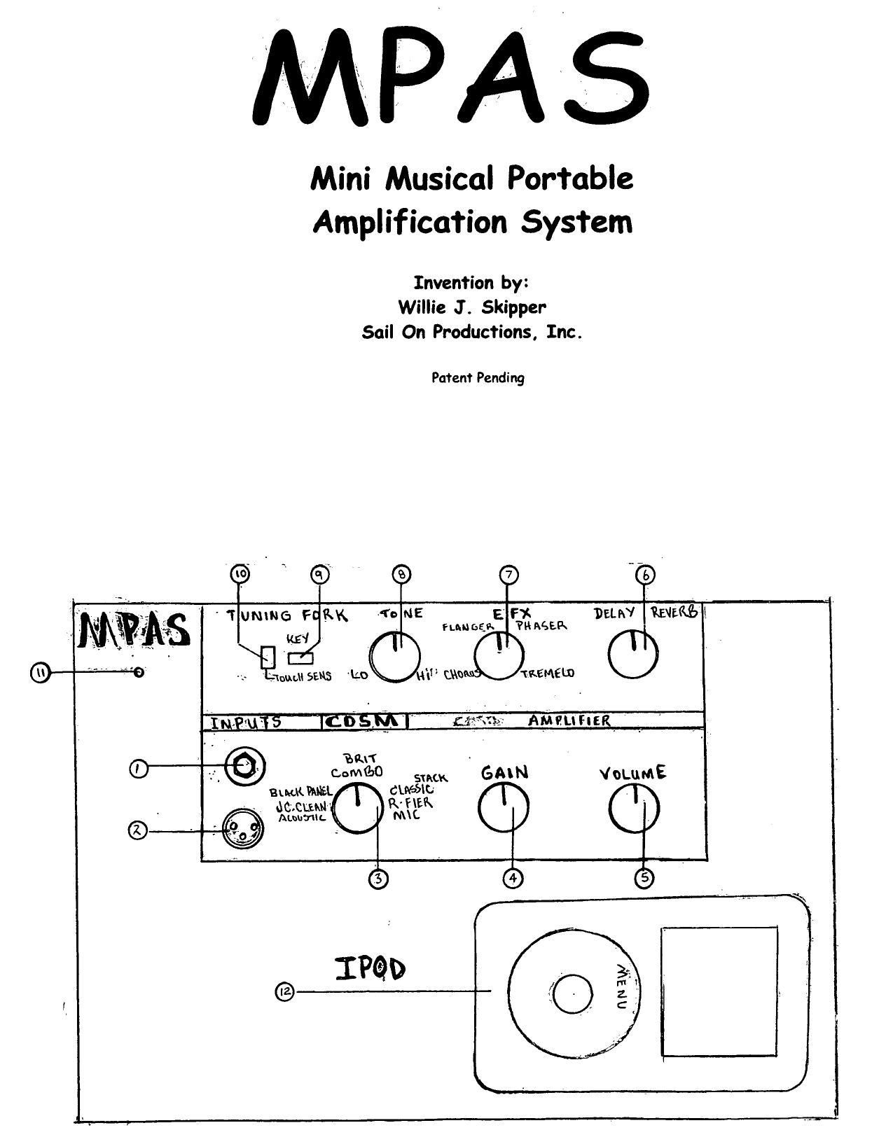

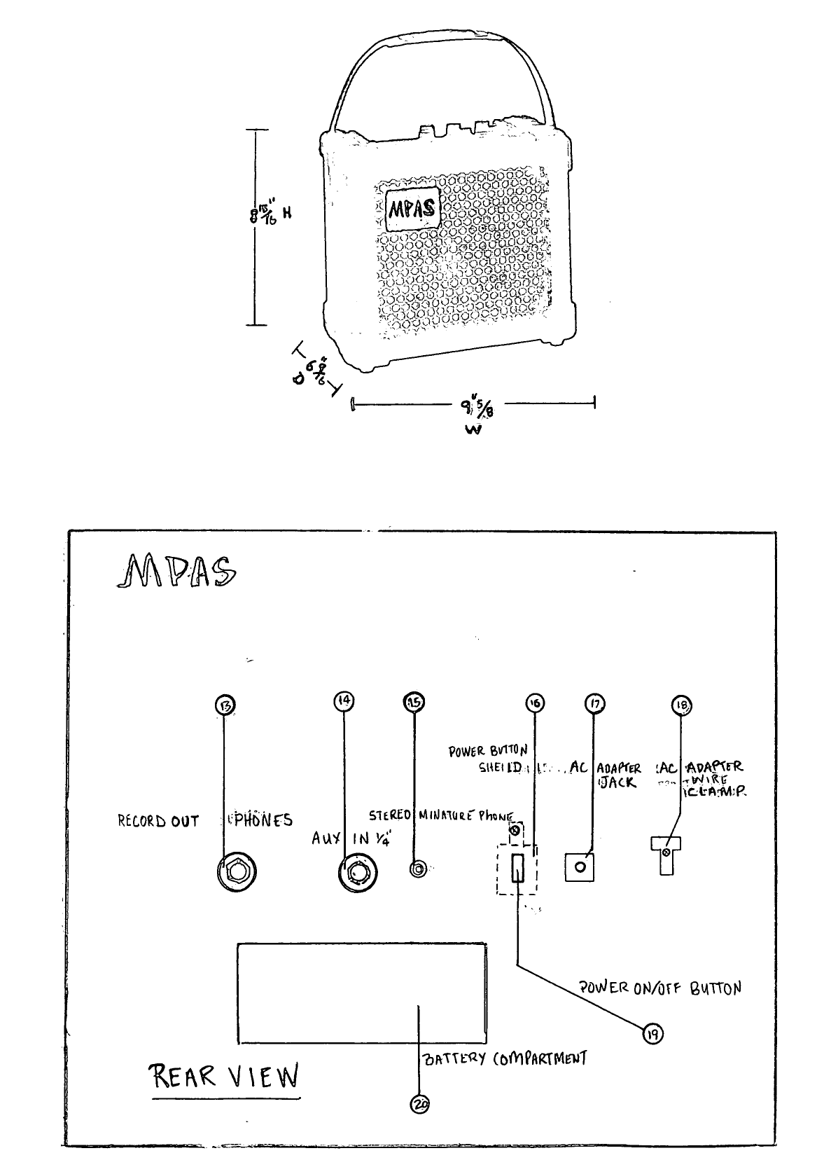

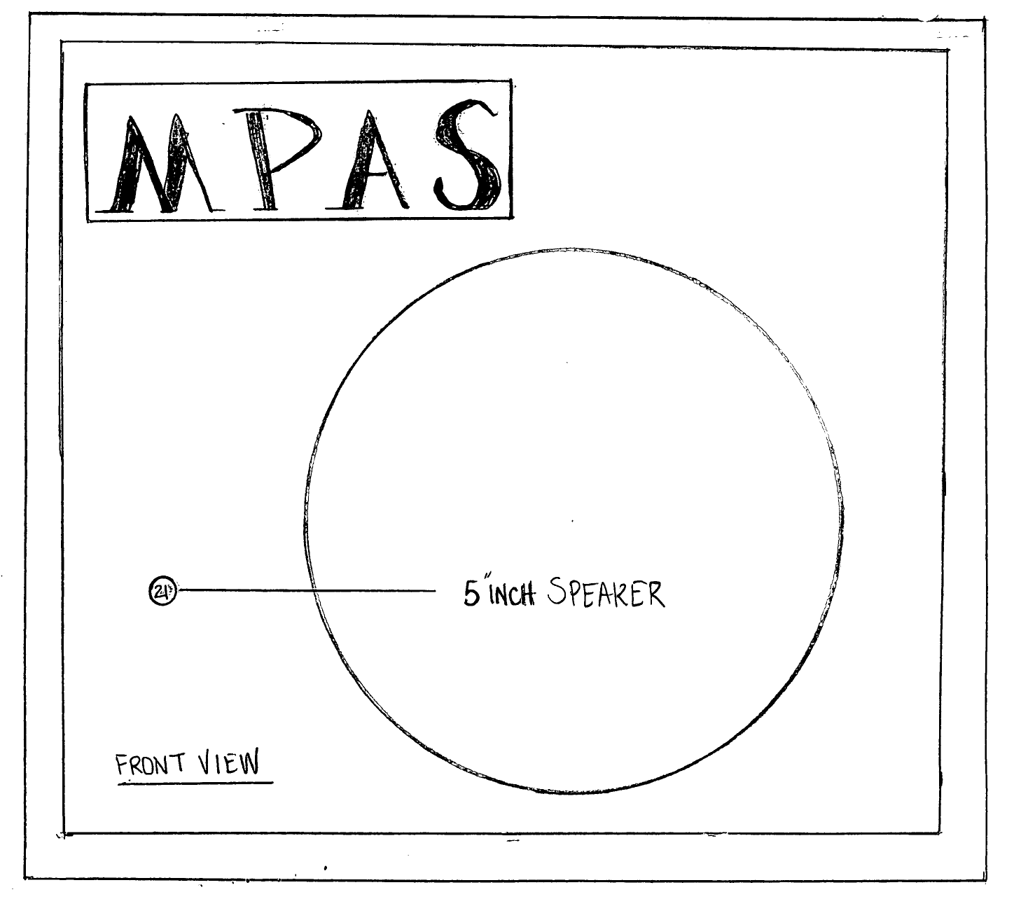

1. ¼ “Line/High Impendence

2. 3 Pin Low Impendence

3. COSM Amp Control

4. Gain Control

5. Volume control

6. Delay/Reverb Control

7. Effects Control

8. Tone Control

9. Tuning Fork Key Selector

10. Tuning Fork Button: Touch Sensitive

11. Indicator Lights: Power LED

12. (iPod) Docking Station

13. Record Out/Phones

14. Auxiliary In

15. Stereo miniature Phone

16. Shield for power button

17. AC Adapter Jack—DC 9 Volt: AC adaptor

18. AC Adaptor Wire Clamp

19. Power on/off Button

20. Battery Compartment (6 Type Batteries)

21. 5″ inch Speaker (12 cm)

The reference No. 60/659,108 was filed Mar. 8, 2005. Confirmation No. 8112

### BRIEF DESCRIPTION

The MPAS acronyms means

Mini musical

Portable

Amplification

System

The MPAS is a modification and integration of four musical components as follows:
1. Amplifier: by the Roland Corporation
2. Ipod: by McIntosh Corporation
3. ¼ input for Guitar or Keyboard
4. 3-Pin input for Microphone

The unit is designed to allow musicians maneuverability with their performances in small venues and locations. The unit can play back stored songs thereby giving the musician access to their complete music library (5 to 40 GB storage capacity). The unit is powered by 6 AA batteries or A/C adaptor.

1. I Willie J. Skipper hereby claim that I am the sole inventor of the MPAS (Mini Musical Amplification System). The invention specs contain no new matter and are a continuation of a previous provisional application (The reference No. 60/659,108 was filed Mar. 8, 2005. Confirmation No: 8112). Any correspondence may be sent to 3599 Warbler Drive, Decatur Ga. 30034.
